(19) United States
(12) Patent Application Publication
(10) Pub. No.: US 2025/0238586 A1
(43) Pub. Date: Jul. 24, 2025

(54) SYSTEM FOR AUTO-GENERATING ARRANGEMENT

(71) Applicant: AIP Technology Corporation, Grand Cayman (KY)

(72) Inventors: Tung-Yang CHEN, Zhubei City (TW); Yu-Ting HUANG, Hsinchu City (TW); Chu HSU, Zhubei City (TW)

(73) Assignee: AIP Technology Corporation, Grand Cayman (KY)

(21) Appl. No.: 18/610,430

(22) Filed: Mar. 20, 2024

(30) Foreign Application Priority Data
Jan. 23, 2024 (TW) 113102566

(51) Int. Cl. G06F 30/392; G06F 30/398

(52) U.S. Cl. CPC G06F 30/392; G06F 30/398

(57) ABSTRACT

A system for auto-generating arrangement is configured to generate a virtual integrated circuit (IC) layout. The system for auto-generating arrangement includes a grouping module and an arranging module. The grouping module receives an electronic file that includes the device structures of testing devices and divides the testing devices into different testing device groups according to classification conditions. The arranging module, connected to the grouping module, arranges the different testing device groups in a virtual area based on an arrangement rule to form the virtual IC layout. Accordingly, the system can shorten design time, reduce labor, and avoid errors caused by manual work. Simultaneously, the testing devices of different types/heights/widths can be arranged in a limited space to automatically generate a virtual IC layout.

### BACKGROUND OF THE INVENTION

This application claims priority for the TW patent application No. 113102566 filed on 23 Jan. 2024, the content of which is incorporated by reference in its entirely.

### FIELD OF THE INVENTION

The present invention relates to a semiconductor technical field, particularly to a system for auto-generating arrangement that is configured to generate a virtual integrated circuit (IC) layout.

### DESCRIPTION OF THE RELATED ART

With the advancement of semiconductor manufacturing technology, integrated circuits (ICs) can integrate a large number of tiny transistors into one chip. As integrated circuits continue to develop toward miniaturization, each chip can package more circuits and the number of transistors endlessly increases. At the same time, in order to prevent integrated circuits from being threatened and damaged by electrostatic discharge events, all pads coupled to the outside must be equipped with electrostatic discharge protection designs. However, with the evolution of semiconductor manufacturing processes, electrostatic discharge protection technology has become increasingly difficult.

The “electrostatic discharge protection device” in the integrated circuit is a special circuit used to prevent electrostatic discharge damage to the integrated circuit. The electrostatic discharge protection device in the integrated circuit is usually designed at the input/output port of the circuit to provide an electrostatic discharge current path to prevent electrostatic discharge current from flowing into the internal circuit of the integrated circuit and causing damage during the electrostatic discharge event. Some common electrostatic discharge protection devices include diodes, metal-oxide semiconductor field-effect transistors (MOSFETs), and bidirectional silicon-controlled rectifiers (SCRs). The selection of these devices depends on the application and design requirements of the integrated circuit.

In the design process of electrostatic protection devices on integrated circuits, most devices still rely on engineers to draw them, which will cost a lot of manpower and time. As shown in FIG. 1, the conventional technology uses a computer to distinguish the types of devices, and then manually sorts the devices according to their types. The types in FIG. 1 include 2TMN/3TMN, 2TGRN, 4TGRN, 2TGGN, etc. However, engineers still need to draw testing devices during design to manually arrange the electrostatic devices in the area, thereby resulting in many blank and unused areas, such that the production capacity cannot be improved. Moreover, the design cycle of IC design is usually long and the cost is related to the complexity, manufacturing process, manufacturing equipment, material selection and other factors of the design. Therefore, in order to overcome the foregoing problems, the present invention provides a system for auto-generating arrangement, so as to increase production capacity, shorten the research and development cycle, reduce costs, and further overcome the conventional problems. The system for auto-generating arrangement can arrange multiple testing devices of different types/heights/widths in a limited space to automatically generate a virtual integrated circuit layout to solve the problems caused by the conventional technology.

### SUMMARY OF THE INVENTION

One objective of the present invention is to provide a system for auto-generating arrangement, which shortens design time, reduces labor, and avoids errors caused by manual operation.

One objective of the present invention is to provide a system for auto-generating arrangement, which can arrange testing devices of different types/heights/widths in a limited space to automatically generate a virtual integrated circuit (IC) layout.

According to the foregoing objectives, the present invention provides a system for auto-generating arrangement applied to electronic equipment. The electronic equipment uses the system for auto-generating arrangement to generate a virtual integrated circuit (IC) layout. The system for auto-generating arrangement includes a grouping module and an arranging module. The grouping module is configured to receive an electronic file that includes the device structures of testing devices and divide the testing devices into different testing device groups according to classification conditions. The arranging module is connected to the grouping module and configured to arrange the different testing device groups in a virtual area based on an arrangement rule to form the virtual IC layout.

In an embodiment, the virtual area includes test lines. The arranging module is configured to arrange the testing devices that are grouped in each of the test lines. The arranging module is configured to mark test line information and the device information of each of the testing devices on each of the test lines. The classification conditions include device type conditions and device height conditions. The arrangement rule is defined to determine whether an entire width of the type and height groups meets an available space width within the virtual area.

In an embodiment, the system for auto-generating arrangement further includes a storage module and a generating module. The storage module includes a design orthogonal table and a device parameter table. The generating module is connected to the storage module and the grouping module and configured to generate a plurality of sets of parameter names based on the design orthogonal table and the device parameter table, draw the device structures of the testing devices according to the plurality of sets of parameter names, convert the device structures of the testing devices into the electronic file, and output the electronic file.

To sum up, the system for auto-generating arrangement is used to generate a virtual integrated circuit layout. The present invention can achieve automatic generation, grouping and arrangement and accurately fills the testing device in the available space, which can effectively shorten the design process, save a lot of manpower and operation time, and improve accuracy to avoid manual errors caused by using the conventional technology.

Below, the embodiments are described in detail in cooperation with the drawings to make easily understood the technical contents, characteristics and accomplishments of the present invention.

### BRIEF DESCRIPTION OF THE DRAWINGS

FIG. 1 is a schematic diagram illustrating an integrated circuit layout of a conventional technology;

FIG. 2 is a schematic diagram illustrating a system for auto-generating arrangement according to a first embodiment of the present invention;

FIG. 3 is a flowchart of the first operation of a system for auto-generating arrangement according to a first embodiment of the present invention;

FIG. 4 is a flowchart of the second operation of a system for auto-generating arrangement according to a first embodiment of the present invention;

FIG. 5A is a flowchart of the first operation of a system for auto-generating arrangement according to a second embodiment of the present invention;

FIG. 5B is a flowchart of the second operation of a system for auto-generating arrangement according to a second embodiment of the present invention;

FIG. 6 is a schematic diagram illustrating testing devices arranged in a virtual area by a system for auto-generating arrangement according to an embodiment of the present invention;

FIG. 7 is a schematic diagram illustrating an integrated circuit layout arranged by a system for auto-generating arrangement according to an embodiment of the present invention;

FIG. 8 is a schematic diagram illustrating an enlarged local virtual area R′ of FIG. 6;

FIG. 9 is a schematic diagram illustrating a system for auto-generating arrangement according to a third embodiment of the present invention; and

FIGS. 10A-10B are schematic diagrams illustrating the device structures of testing devices according to a third embodiment of the present invention.

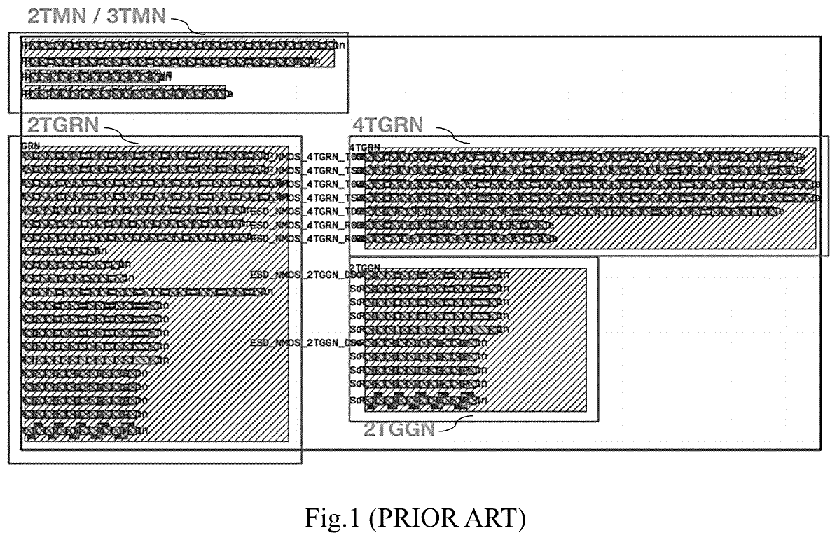

### DETAILED DESCRIPTION OF THE INVENTION

Reference will now be made in detail to embodiments illustrated in the accompanying drawings. Wherever possible, the same reference numbers are used in the drawings and the description to refer to the same or like parts. In the drawings, the shape and thickness may be exaggerated for clarity and convenience. This description will be directed in particular to elements forming part of, or cooperating more directly with, methods and apparatus in accordance with the present disclosure. It is to be understood that elements not specifically shown or described may take various forms well known to those skilled in the art. Many alternatings and modifications will be apparent to those skilled in the art, once informed by the present disclosure.

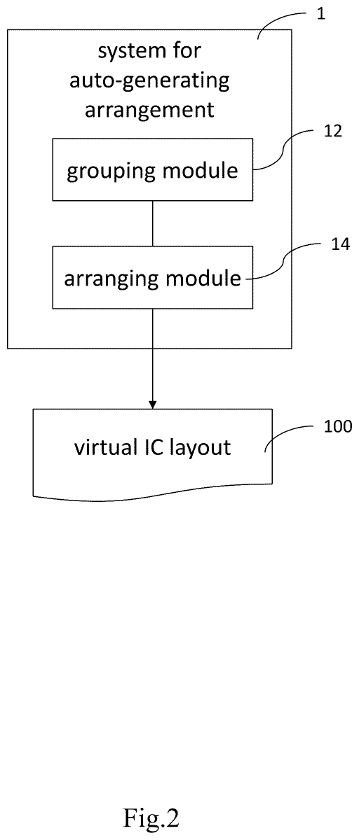

Please refer to FIG. 2. A system 1 for auto-generating arrangement of the present invention is applied to electronic equipment. The electronic equipment uses the system 1 for auto-generating arrangement to generate a virtual integrated circuit (IC) layout 100. The electronic equipment may be, but not limited to, a computer, a notebook computer, an electronic machine, and semiconductor equipment. The system 1 for auto-generating arrangement may be, but not limited to, a program system or a software interface. As shown in FIG. 2, the system 1 for auto-generating arrangement includes a grouping module 12 and an arranging module 14. The grouping module 12 receive an electronic file that includes the device structures of testing devices and divides the testing devices into different testing device groups according to classification conditions. The arranging module 14, connected to the grouping module 12, arranges the different testing device groups in a virtual area based on an arrangement rule to form the virtual IC layout 100. In the embodiment, the electronic file is usually in GDSII format. The testing device is an electrostatic discharge (ESD) device, but the present invention is not limited thereto. The device structure of the testing device is composed of a large number of parameter names. The device structure includes parameters such as a device shape, a device spacing, a device width, etc. Therefore, the electronic file usually includes a large amount of data that are quite complex and cumbersome.

Continuing form the foregoing description, the virtual area includes test lines. The arranging module 14 arranges the testing devices that are grouped in each of the test lines and marks test line information and the device information of each of the testing devices on each of the test lines. The grouping module 12 selects the testing devices that are grouped using random numbers. The arranging module 14 arranges the testing devices that are grouped using random numbers in the virtual area to form the virtual IC layout 100.

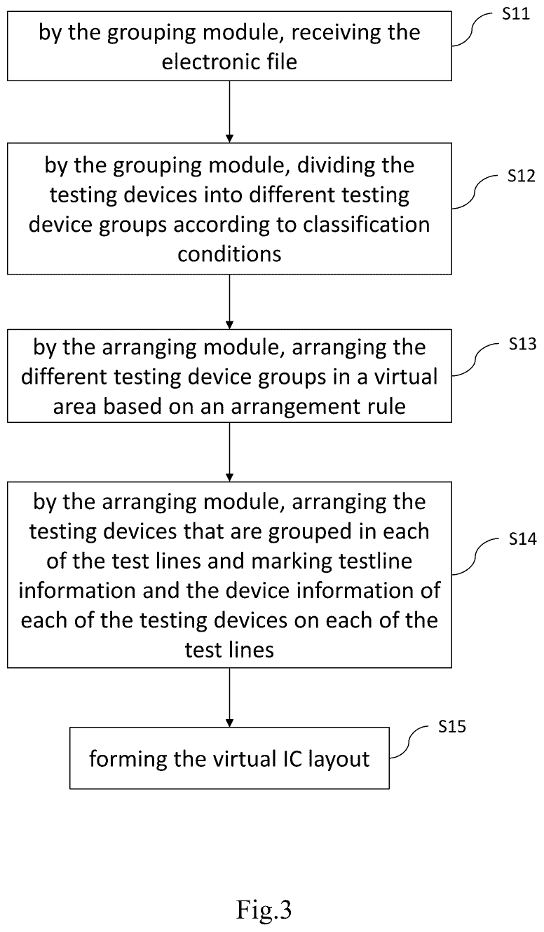

Please refer to FIG. 3. FIG. 3 is a flowchart of the operation of the system 1 for auto-generating arrangement. The flowchart includes:
Step S11: by the grouping module 12, receiving the electronic file;
Step S12: by the grouping module 12, dividing the testing devices into different testing device groups according to classification conditions;
Step S13: by the arranging module 14, arranging the different testing device groups in a virtual area based on an arrangement rule;
Step S14: by the arranging module 14, arranging the testing devices that are grouped in each of the test lines and marking test line information and the device information of each of the testing devices on each of the test lines; and
Step S15: forming the virtual IC layout 100.

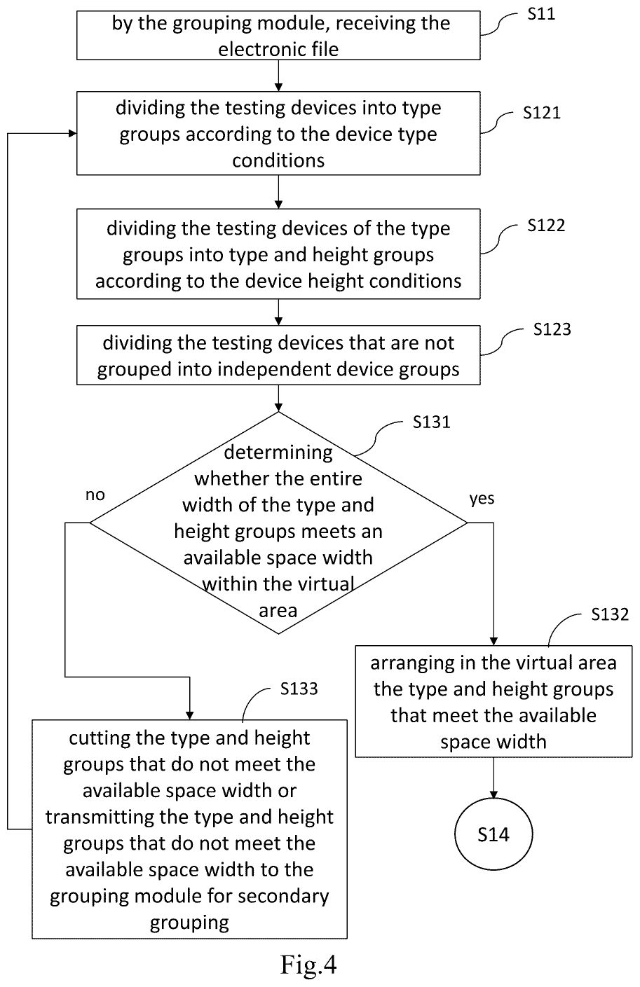

Please refer to FIG. 3 and FIG. 4. FIG. 4 shows that each step in FIG. 3 includes substeps.

In Step S12, the classification conditions include device type conditions and device height conditions. The grouping module can divide the testing devices into different testing device groups according to the device type conditions and the device height conditions.

Step S12 includes the following substeps:
Step S121: dividing the testing devices into type groups according to the device type conditions;
Step S122: dividing the testing devices of the type groups into type and height groups according to the device height conditions; and
Step S123: dividing the testing devices that are not grouped into independent device groups. The type and height groups and all the independent device groups recited in Step S122 and Step S123 are different testing device groups.

In Step S13, the arrangement rule is defined to determine whether the entire width of the type and height groups meets an available space width within the virtual area. Accordingly, Step S13 includes the following substeps:
Step S131: determining whether the entire width of the type and height groups meets an available space width within the virtual area: if yes, performing Step S132; and if no, performing Step S133;
Step S132: arranging in the virtual area the type and height groups that meet the available space width and performing Step S14; and
Step S133: cutting the type and height groups that do not meet the available space width or transmitting the type and height groups that do not meet the available space width to the grouping module for secondary grouping, and then returning to Step S121.

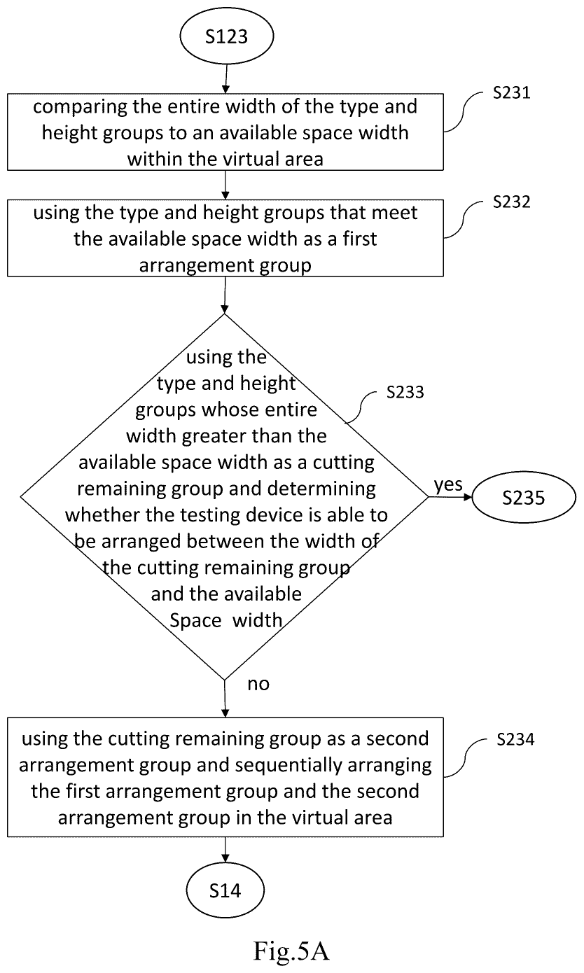

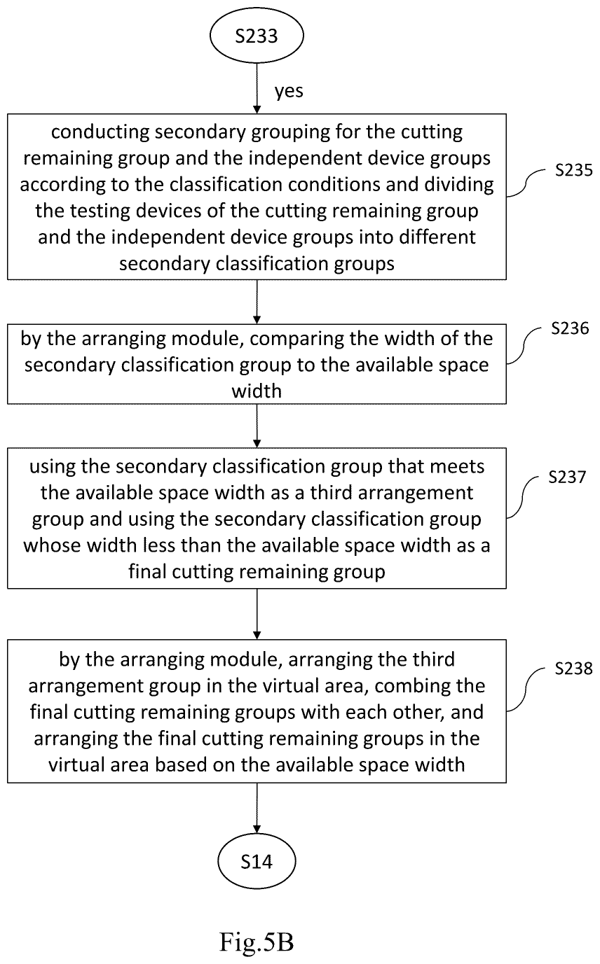

Please refer to FIGS. 5A-5B. FIGS. 5A-5B are different from FIG. 4 in that Steps S131-133 are replaced with Steps S231-S238. For clarity, FIGS. 5A-5B merely show Steps S231-S238. After Step S123, Step S231 is performed to compare the entire width of the type and height groups to an available space width within the virtual area. In Step S232, the type and height groups that meet the available space width are used as a first arrangement group. In Step S233, the type and height groups whose entire width greater than the available space width are used as a cutting remaining group and it is determined whether the testing device is able to be arranged between the width of the cutting remaining group and the available space width. When the testing device is not able to be arranged between the width of the cutting remaining group and the available space width, Step S234 is performed. In Step S234, the cutting remaining group is used as a second arrangement group and the arranging module sequentially arranges the first arrangement group and the second arrangement group in the virtual area. When there is a space for arranging a testing device between a width of the cutting remaining group and the available space width, Step S235 is performed. In Step S235, the grouping module conducts secondary grouping for the cutting remaining group and the independent device groups according to the classification conditions and divides the testing devices of the cutting remaining group and the independent device groups into different secondary classification groups. After Step S235, Step S236 is performed. In Step S236, the arranging module compares the width of the secondary classification group to the available space width. In Step S237, the secondary classification group that meets the available space width is used as a third arrangement group and the secondary classification group whose width less than the available space width is used as a final cutting remaining group. In Step S238, the arranging module arranges the third arrangement group in the virtual area, combines the final cutting remaining groups with each other, and arrange the final cutting remaining groups in the virtual area based on the available space width.

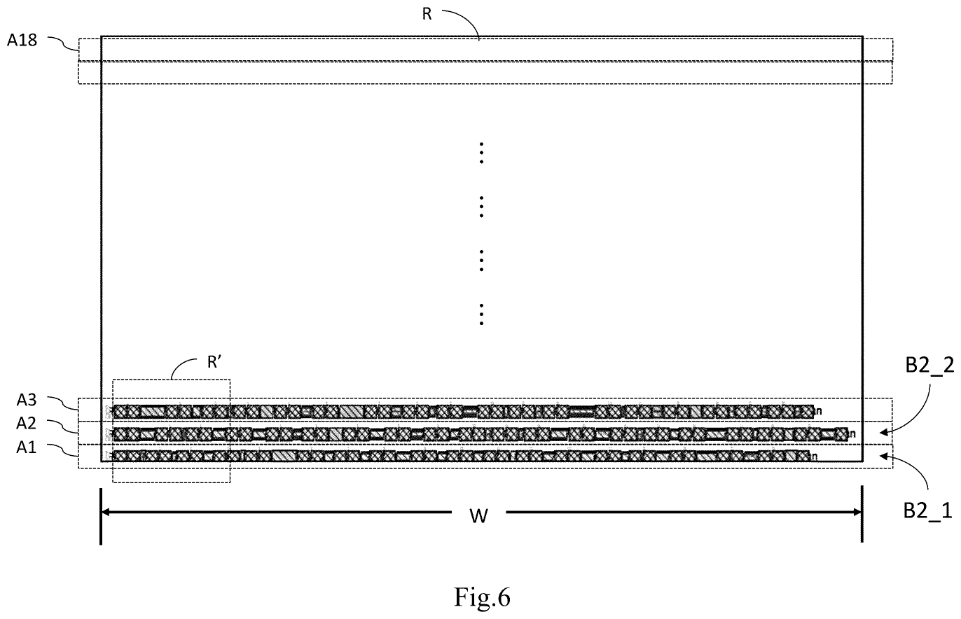

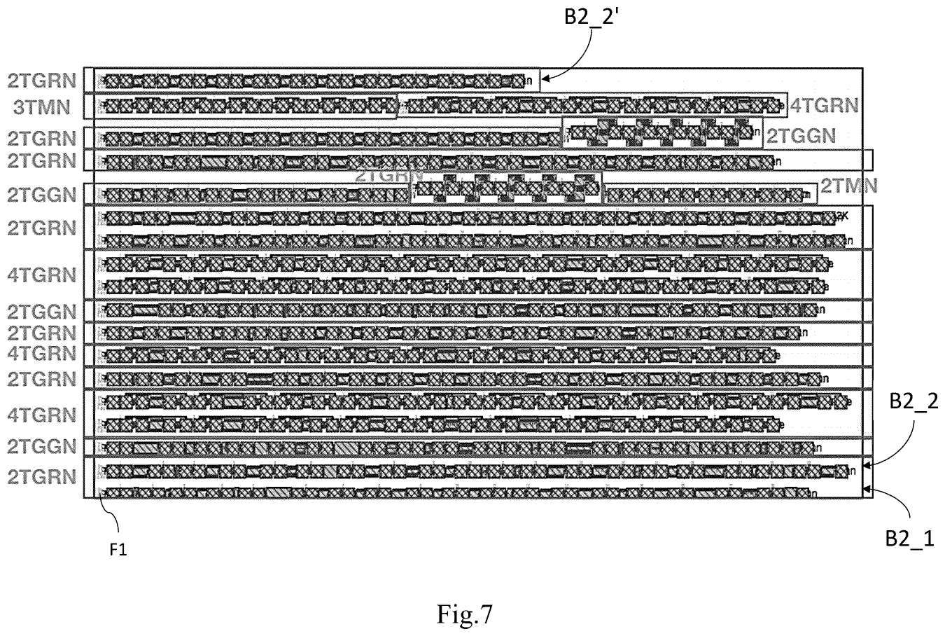

Please refer to FIG. 6 and FIG. 7. In order to enable those skilled in the art to better understand the technology of the present invention, please refer to FIGS. 2-5B of the present invention for the following detailed description. In FIG. 6, the virtual region R includes test lines A1, A2, A3-A18 (test lines A13-A18 are omitted and not shown). In order to clearly identify the types of all testing devices, FIG. 7 marks the names of the device types of the testing devices (including device types 2TGGN, 2TGRN, 2TMN, 3TMN, and 4TGRN) for easier understanding.

Firstly, the grouping module receives the electronic file such as a GDSII file and divides the testing devices into type groups according to the device type conditions. For example, the device types of the testing devices include 2TGGN, 2TGRN, 2TMN, 3TMN, and 4TGRN. The grouping module divides the testing devices into type groups B1-B5 according to the five device types. For example, the device type of the type group B1 is 2TGGN, the device type of the type group B2 is 2TGRN, the device type of the type group B3 is 2TMN, the device type of the type group B4 is 3TMN, and the device type of the type group B5 is 4TGRN.

Then, the grouping module divides the testing devices of the type groups B1-B5 into type and height groups (e.g., type and height groups B2_1 and B2_2) according to the device height conditions. The embodiment does not show the type of a single testing device. However, when the type and height group has a single testing device, the grouping module divides the remaining single testing device that is not grouped into the independent device group as shown by Step S123.

Furthermore, the arranging module can compare the entire width of the type and height groups to an available space width within the virtual area. As shown in FIG. 6, the available space width W of the virtual area R can be designed by a designer. The available space width W can be slightly less than or equal to the edge of the virtual area R. The available space width W can alternatively have a range. When the entire width of the type and height groups is within the range, the entire width of the type and height groups meets the available space width W. The arranging module arranges in the virtual area the type and height groups that meet the available space width W. The arranging module cuts the type and height groups that do not meet the available space width or transmits the type and height groups that do not meet the available space width to the grouping module for secondary grouping.

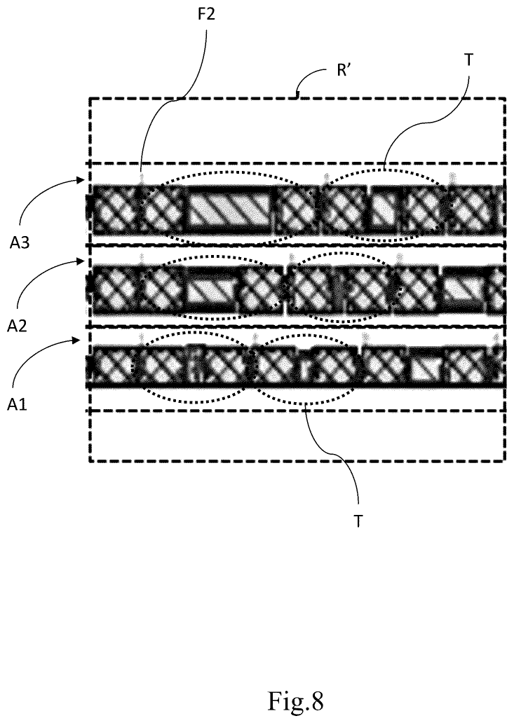

As shown in FIG. 6, the type and height group B2_1 that meets the available space width W is used as a first arrangement group. As shown in FIG. 7, the type and height group B2_2 and the cutting remaining group B2_2′ originally belong to the same type and height group. However, in the comparison process, the type and height group B2_2 and the cutting remaining group B2_2′ are greater than the available space width W. Thus, the type and height groups greater than the available space width W are cut into a second arrangement group (i.e., type and height group B2_2) and the cutting remaining group B2_2′. Based on the foregoing principle of the system, the system for auto-generating arrangement of the present invention can sequentially arrange the first arrangement group and the second arrangement group in the virtual area and further the testing devices of a third arrangement group and the final cutting remaining group in each of the test lines. FIG. 8 shows an enlarged local virtual area R′ of FIG. 6. As shown in FIG. 8, there are testing devices T (encircled by dashed ellipses) in the test lines (e.g., test lines A1, A2, and A3 in FIG. 8). The present invention can effectively use the entire range, sequentially arranges the testing devices T in the virtual area R, and fills the testing device T in a limited space. As shown in FIG. 7 and FIG. 8, the arranging module marks test line information F1 and the device information F2 of the testing devices T on each of the test lines. In FIG. 8, each dashed ellipse encircles a single testing device T. The device information F2 of each testing device T will be marked at the beginning of each testing device T to facilitate subsequent experimental collection and tests.

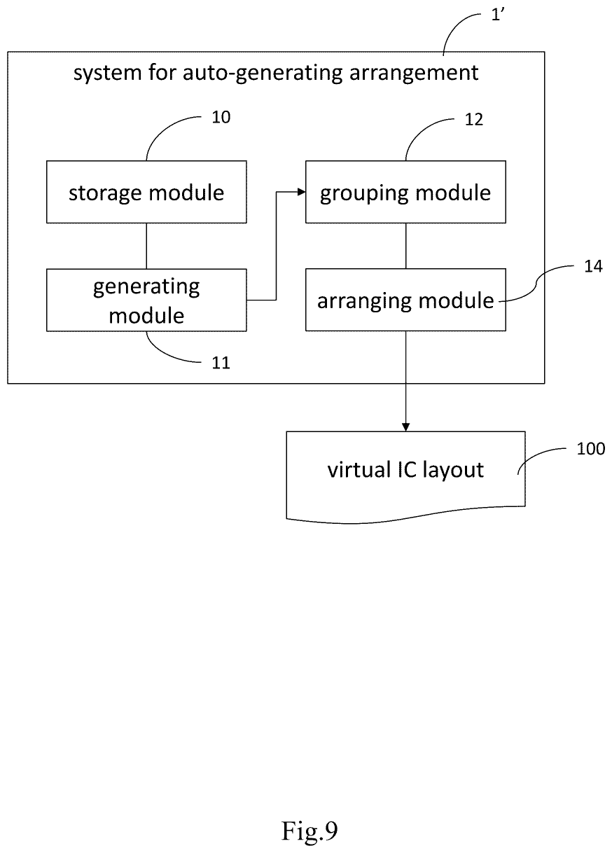

Please refer to FIG. 9. In the embodiment, a system 1′ for auto-generating arrangement includes the grouping module 12, the arranging module 14, a storage module 10, and a generating module 11. The storage module 10 includes a design orthogonal table and a device parameter table. The generating module 11 is connected to the storage module 10 and the grouping module 12. The generating module 11 generates a plurality of sets of parameter names based on the design orthogonal table and the device parameter table, draws the device structures of the testing devices according to the plurality of sets of parameter names, converts the device structures of the testing devices into the electronic file, and outputs the electronic file. The storage module 10 can be, but not limited to, an in-system database, a cloud database, a network-attached storage device (NAS), or a random access memory (RAM), a read-only memory (ROM), or a solid-state drive (SSD).

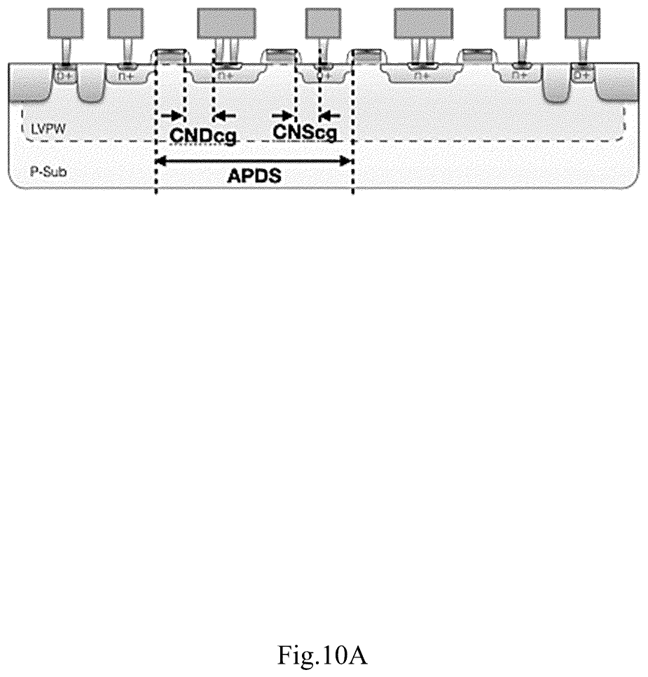

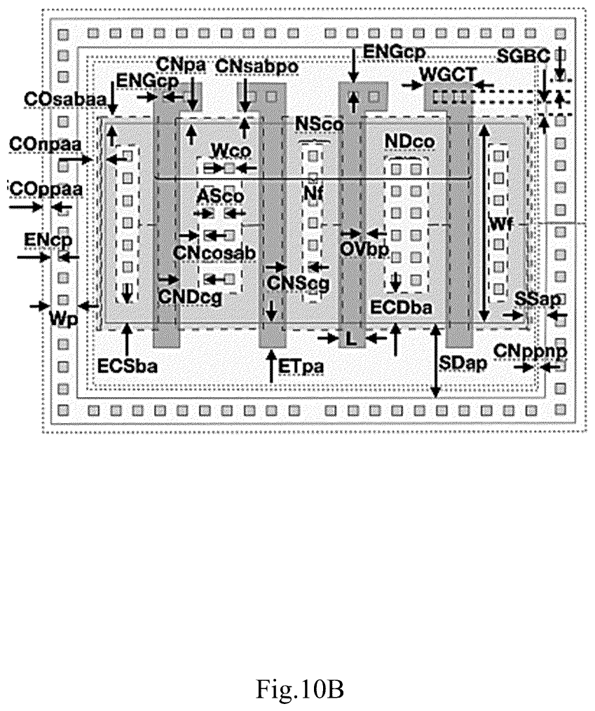

As shown in FIG. 10A and FIG. 10B, the parameter names include, but are not limited to, CNDcg, CNScg, APDS, ENGcp, SGBC, CNppaa, CNsabaa, WGCT, NSco, Wco, CNDCg, COppaa, ENcp, ASco, CNcosab, CNScg, Wp, NDco, ECDba, Wf, ECSba, ETpa, SDap, CNppnp, etc. The texts marked above are all parameter names and definitions well known by those skilled in the art. The storage unit stores a built-in device parameter table, and uses the Taguchi method in the design of experiment (DOE) to design testing devices. The following description takes ESD devices as an example. The generation module, generating a plurality of sets parameter names based on the design orthogonal table and the device parameter table, configured to: (1) define the performance targets of ESD devices, including those of ESD protection level, operating voltage, ESD tolerance, etc. (2) define design factors, including those of material properties, device structure, geometric, size, etc. (3) generate a plurality of sets of parameter names. After generating the parameter names, the generation module will draw the devices according to the parameter names. The devices are what the present invention calls testing devices (i.e.,Testkey). The plurality of sets of parameter names include one or a combination of a device shape, a device spacing, and a device width of the testing device.

In the process of using the sets of parameters generated by the Taguchi method, the important parameters that affect the results of this experiment are firstly defined, such as “L/Channel Length”, “Nf/Channel Finger Number”, and “Wf/Channel Finger” Width”. That is to say, using the Taguchi method, two categories are defined and an L4 orthogonal table is generated, which means that four experiments need to generate four testing devices. Instead of manually drawing the four testing devices, the generation module of the present invention auto-generates the four testing devices to avoid errors caused by manual drawing.

In conclusion, the present invention provides a system for auto-generating, sorting, and adding test labels to testing devices to save a lot of manpower and avoid errors that may occur in manual operations, so that operators only need to perform the design of experiment to fully auto-generate files for delivery to customers.

The embodiments described above are only to exemplify the present invention but not to limit the scope of the present invention. Therefore, any equivalent modification or variation according to the shapes, structures, features, or spirit disclosed by the present invention is to be also included within the scope of the present invention.

What is claimed is:

1. A system for auto-generating arrangement applied to electronic equipment, the electronic equipment using the system for auto-generating arrangement to generate a virtual integrated circuit (IC) layout, and the system for auto-generating arrangement comprising:
a grouping module configured to receive an electronic file that comprises device structures of testing devices and divide the testing devices into different testing device groups according to classification conditions; and
an arranging module connected to the grouping module and configured to arrange the different testing device groups in a virtual area based on an arrangement rule to form the virtual IC layout.

2. The system for auto-generating arrangement according to claim 1, wherein the virtual area comprises test lines and the arranging module is configured to arrange the testing devices that are grouped in each of the test lines.

3. The system for auto-generating arrangement according to claim 2, wherein the arranging module is configured to mark test line information and device information of each of the testing devices on each of the test lines.

4. The system for auto-generating arrangement according to claim 1, wherein the grouping module is configured to select the testing devices that are grouped using random numbers and the arranging module is configured to arrange the testing devices that are grouped using random numbers in the virtual area to form the virtual IC layout.

5. The system for auto-generating arrangement according to claim 1, wherein the classification conditions comprise device type conditions and device height conditions.

6. The system for auto-generating arrangement according to claim 5, wherein the grouping module is configured to divide the testing devices into type groups according to the device type conditions, divide the testing devices of the type groups into type and height groups according to the device height conditions, and finally divide the testing devices that are not grouped into independent device groups, wherein the type and height groups and the independent device groups are the different testing device groups.

7. The system for auto-generating arrangement according to claim 6, wherein the arrangement rule is defined to determine whether an entire width of the type and height groups meets an available space width within the virtual area:
if yes, arranging in the virtual area the type and height groups that meet the available space width; and
if no, cutting the type and height groups that do not meet the available space width or transmitting the type and height groups that do not meet the available space width to the grouping module for secondary grouping.

8. The system for auto-generating arrangement according to claim 6, wherein the arranging module is configured to compare an entire width of the type and height groups to an available space width within the virtual area, use the type and height groups that meet the available space width as a first arrangement group, use the type and height groups whose entire width greater than the available space width as a cutting remaining group, and determine whether the testing device is able to be arranged between a width of the cutting remaining group and the available space width; when the testing device is not able to be arranged between a width of the cutting remaining group and the available space width, the cutting remaining group is used as a second arrangement group and the arranging module sequentially arranges the first arrangement group and the second arrangement group in the virtual area.

9. The system for auto-generating arrangement according to claim 8, wherein the arranging module is configured to determine whether the testing device is able to be arranged between a width of the cutting remaining group and the available space width, wherein when there is a space for arranging a testing device between a width of the cutting remaining group and the available space width, the grouping module conducts secondary grouping for the cutting remaining group and the independent device groups according to the classification conditions and divides the testing devices of the cutting remaining group and the independent device groups into different secondary classification groups, and the arranging module is configured to compare a width of the secondary classification group to the available space width, use the secondary classification group that meets the available space width as a third arrangement group, use the secondary classification group whose width less than the available space width as a final cutting remaining group, arrange the third arrangement group in the virtual area, and combine the final cutting remaining groups with each other and arrange them in the virtual area based on the available space width.

10. The system for auto-generating arrangement according to claim 9, wherein the virtual area comprises test lines and the arranging module is configured to arrange the testing devices of the first arrangement group, the second arrangement group, the third arrangement group, and the final cutting remaining group in each of the test lines.

11. The system for auto-generating arrangement according to claim 10, wherein the arranging module is configured to mark test line information and device information of each of the testing devices on each of the test lines.

12. The system for auto-generating arrangement according to claim 1, further comprising:
a storage module comprising a design orthogonal table and a device parameter table; and
a generating module connected to the storage module and the grouping module and configured to generate a plurality of sets of parameter names based on the design orthogonal table and the device parameter table, draw device structures of the testing devices according to the plurality of sets of parameter names, convert the device structures of the testing devices into the electronic file, and output the electronic file.

13. The system for auto-generating arrangement according to claim 12, wherein the plurality of sets of parameter names comprise one or a combination of a device shape, a device spacing, and a device width of the testing device.
